(19) United States
(12) Patent Application Publication
(10) Pub. No.: US 2026/0020166 A1
(43) Pub. Date: Jan. 15, 2026

(54) ELECTRICAL JUNCTION BOX

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Taiji YANAGIDA, Osaka (JP); Hiroki SHIMODA, Osaka (JP); Koushi IGURA, Osaka (JP); Yusuke OKUHIRA, Mie (JP); Maiko ISSHIKI, Mie (JP); Kouki AIDA, Mie (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 19/108,295

(22) PCT Filed: Sep. 12, 2023
(86) PCT No.: PCT/JP2023/033258

§ 371 Date: Mar. 3, 2025

(30) Foreign Application Priority Data
Sep. 14, 2022 (JP) 2022-146343

(51) Int. Cl. H05K 5/02; H02G 3/08; H02G 3/16; H05K 7/20

(52) U.S. Cl. CPC H05K 5/0213; H02G 3/081; H02G 3/16; H05K 7/20127

(57) ABSTRACT

An electrical junction box includes: a housing in which a relay and a fuse are provided, the housing having a fixing wall to be fixed to a target object; a plate-shaped bus bar arranged opposing the fixing wall and connected to the relay and the fuse; and a plurality of heat dissipation plates provided standing in a direction intersecting the bus bar, and configured to dissipate heat from the bus bar.

### TECHNICAL FIELD

The present disclosure relates to an electrical junction box.

This application claims priority to Japanese Application No. 2022-146343, filed on Sep. 14, 2022, the entire disclosure of which is hereby incorporated herein by reference.

### BACKGROUND ART

Conventionally, many vehicles include an electrical connection device that is provided between a power source and an electrical device and supplies electric power from the power source to the electrical device.

Patent Document 1 discloses an electrical connection device that includes a housing for housing an electromagnetic relay, and the housing has an opening provided in the vicinity of the electromagnetic relay to dissipate heat from the inside of the housing to the outside.

### CITATION LIST

### Patent Documents

Patent Document 1: JP 2021-83160A

### SUMMARY OF INVENTION

An electrical junction box according to an embodiment of the present disclosure includes: a housing in which an electronic component is provided, the housing having a fixing wall configured to be fixed to a target object; a plate-shaped bus bar arranged opposing the fixing wall and connected to the electronic component; and a plurality of heat dissipation plates provided standing in a direction intersecting the bus bar, and configured to dissipate heat from the bus bar.

### BRIEF DESCRIPTION OF DRAWINGS

FIG. 1 is a perspective view of an electrical junction box according to a first embodiment.

FIG. 2 is a plan view of the electrical junction box according to the first embodiment.

FIG. 3 is a plan view showing the electrical junction box according to the first embodiment with an upper case removed.

FIG. 4 is a view taken along an arrow IV in FIG. 3.

FIG. 5 is a cross-sectional view taken along a line V-V in FIG. 2.

FIG. 6 is a partial plan view of an electrical junction box according to a second embodiment.

FIG. 7 is a partial vertical cross-sectional view of an electrical junction box according to a third embodiment.

FIG. 8 is a plan view of an electrical junction box of a fourth embodiment with an upper case removed.

### PROBLEMS TO BE SOLVED BY PRESENT DISCLOSURE

For example, in the case of an electronic component such as a relay that generates heat during energization, in reality, it is not possible to expect a significant heat dissipation effect by the dissipation of heat from the electronic component itself, and it is more efficient to perform heat dissipation via a bus bar that is connected to such an electronic component and is exposed to the air.

However, in the electrical connection device of Patent Document 1, the opening is provided in the housing at a position in the vicinity of the electromagnetic relay, and heat is only dissipated from the electromagnetic relay itself, with no consideration given to heat dissipation via a bus bar, thus making it difficult to say that heat is efficiently dissipated from the electromagnetic relay.

In view of this, an object of the present invention is to provide an electrical junction box that can more effectively dissipate heat generated by an electronic component when energized.

### Advantageous Effects of Present Disclosure

According to the present disclosure, heat from an electronic component that generates heat when energized can be dissipated more effectively.

### Description of Embodiments of Present Disclosure

First, embodiments of the present disclosure will be listed and described. Also, at least some of the embodiments described below may be combined as desired.
(1) An electrical junction box according to an embodiment of the present disclosure includes: a housing in which an electronic component is provided, the housing having a fixing wall configured to be fixed to a target object; a plate-shaped bus bar arranged opposing the fixing wall and connected to the electronic component; and a plurality of heat dissipation plates provided standing in a direction intersecting the bus bar, and configured to dissipate heat from the bus bar.

In this embodiment, due to the heat dissipation plates being provided, heat generated by the electronic component during energization and transmitted to the bus bar can be quickly dissipated, and heat from the electronic component can be dissipated more effectively.
(2) In the electrical junction box according to an embodiment of the present disclosure, the electrical junction box further includes: a base plate having a first main surface in contact with a main surface of the bus bar, wherein the plurality of heat dissipation plates are provided on a second main surface of the base plate.

In this embodiment, heat generated by the electronic component during energization is transferred to the bus bar and then conducted via the base plate to the heat dissipation plates, and the heat dissipation plates quickly dissipate the heat. Therefore, heat from the electronic component can be dissipated effectively.
(3) In the electrical junction box according to an embodiment of the present disclosure, a first through hole is formed in an opposing wall opposing the fixing wall, and the first through hole is formed at a position that, with respect to an opposing direction in which the fixing wall and the opposing wall oppose each other, corresponds to a gap between an adjacent pair of the heat dissipation plates.

In this embodiment, the first through hole is formed at a position that, with respect to the opposing direction, corresponds to the gap between the pair of adjacent heat dissipation plates. Therefore, outside air flowing into the housing through the first through hole quickly flows into the gap between the heat dissipation plates and air-cools the heat dissipation plates, and the heated air in the gap between the heat dissipation plates rises and quickly flows to the outside of the housing through the first through hole. Therefore, heat from the electronic component can be dissipated effectively.
(4) In the electrical junction box according to an embodiment of the present disclosure, the first through hole extends along the heat dissipation plates.

In this embodiment, the first through hole extends along the heat dissipation plates, and therefore the size of the first through hole can be effectively ensured in the portion of the opposing wall that corresponds to the gap between the adjacent heat dissipation plates.
(5) In the electrical junction box according to an embodiment of the present disclosure, a pair of side walls are provided at respective opposing edges of the opposing wall and extend toward the fixing wall, a second through hole is formed in each of the side walls, and the second through holes are each formed at a position that, with respect to an opposing direction in which the two side walls oppose each other, corresponds to a gap between an adjacent pair of the heat dissipation plates.

In this embodiment, the second through holes are each formed at a position that, with respect to the opposing direction of the two side walls, corresponds to the gap between an adjacent pair of heat dissipation plates, and therefore air flowing in through the second through hole in the side wall on one side passes between the adjacent heat dissipation plates and quickly flows out through the second through hole in the side wall on the other side. At this time, the convection heat from the heat dissipation plates also flows to the outside of the housing, and therefore the effect of cooling the electronic component can be further improved.
(6) In the electrical junction box according to an embodiment of the present disclosure, the second through holes extend along the plurality of heat dissipation plates.

In this embodiment, the second through holes extend along the heat dissipation plates, and therefore the size of the second through holes can be effectively secured in the portions of the two side walls that correspond to the gap between the adjacent heat dissipation plates.
(7) In the electrical junction box according to an embodiment of the present disclosure, the base plate and the plurality of heat dissipation plates are integrally formed as a single piece, and the opposing wall is provided with a positioning portion configured to position the plurality of heat dissipation plates.

In this embodiment, the positioning portion is used to position the heat dissipation plates during assembly, and therefore the assembly work can be made easier.
(8) In the electrical junction box according to an embodiment of the present disclosure, the plurality of heat dissipation plates are provided in a vicinity of a connection portion between the bus bar and the electronic component.

In this embodiment, heat dissipation plates are also provided in the vicinity of the connection portion between the bus bar and the electronic component. Therefore, the connection portion, where the generation of heat is concentrated during energization, can be cooled more efficiently.
(9) In the electrical junction box according to an embodiment of the present disclosure, a larger number of the heat dissipation plates are provided in a vicinity of the connection portion than in another region.

In this embodiment, the number of heat dissipation plates in the vicinity of the connection portion between the bus bar and the electronic component is greater than in other regions. Therefore, the connection portion, where the generation of heat is concentrated during energization, can be cooled more efficiently.
(10) In the electrical junction box according to an embodiment of the present disclosure, a plurality of the first through holes are provided, and among the plurality of first through holes, a first through hole formed in a vicinity of a connection portion between the bus bar and the electronic component is larger than the other first through holes.

In this embodiment, the first through hole formed in the vicinity of the connection portion is larger than the other first through holes. Therefore, more outside air can flow in to the connection portion and more air containing heat dissipated from the connection portion can flow out, and the heat generated at the connection portion during energization can be cooled more efficiently.
(11) In the electrical junction box according to an embodiment of the present disclosure, a plurality of the second through holes are provided, and among the plurality of second through holes, a second through hole formed in a vicinity of a connection portion between the bus bar and the electronic component is larger than the other second through holes.

In this embodiment, the second through hole provided in the vicinity of the connection portion is larger than the other second through holes. Therefore, more outside air can flow in to the connection portion and more air containing heat dissipated from the connection portion can flow out, and the heat generated at the connection portion during energization can be cooled more efficiently.

### Details of Embodiments of Present Disclosure

Embodiments of an electrical junction box according to the present disclosure will be described below with reference to the drawings. However, the present invention is not limited to these examples, but rather is defined by the scope of the claims, and is intended to include all modifications within the meaning and scope equivalent to the claims.

### First Embodiment

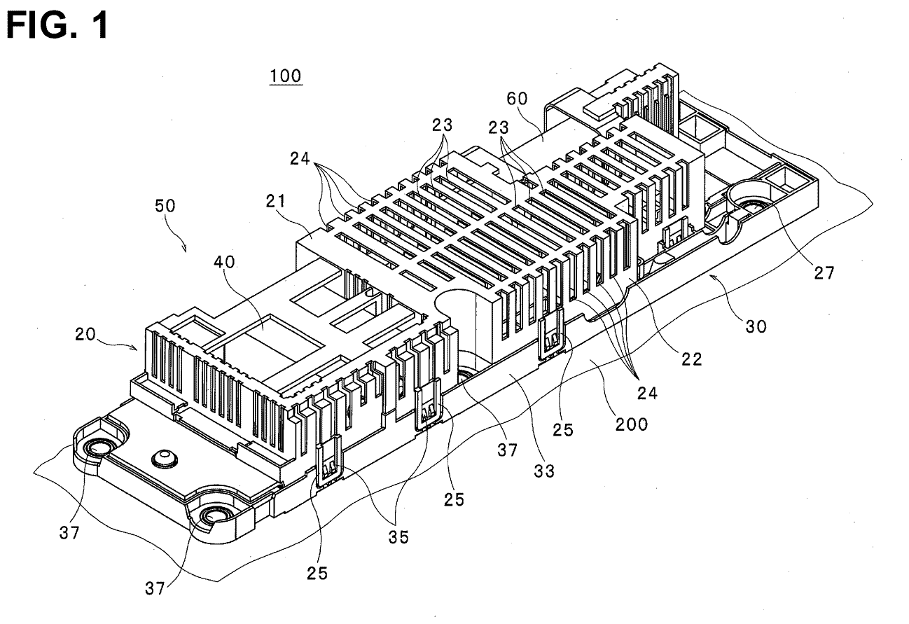

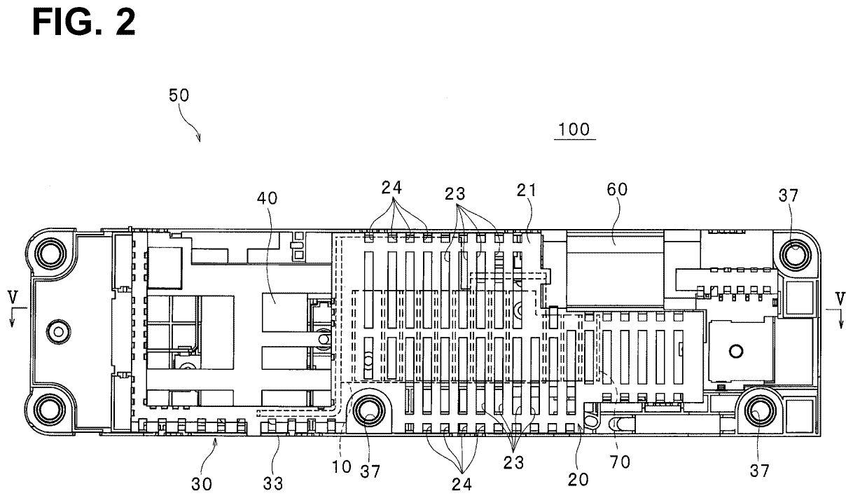

FIG. 1 is a perspective view of an electrical junction box 100 according to a first embodiment, and FIG. 2 is a plan view of the electrical junction box 100 according to the first embodiment. In FIG. 2, the positions of a bus bar 10 and a heat dissipation member 70, which will be described later, are indicated by dashed lines.

The electrical junction box 100 is configured to be attached to the outside of an object (target object) such as a battery pack 200 of an electric vehicle (EV). For convenience, FIG. 1 shows a state in which the electrical junction box 100 is attached to the battery pack 200.

The electrical junction box 100 includes a housing 50 that houses, for example, a relay 40 (electronic component), a fuse 60 (electronic component), a circuit board, and the like. The housing 50 has a substantially rectangular shape in a plan view, and is made of resin, for example.

The housing 50 includes a lower case 30 that is attached to the target object, and an upper case 20 that partially covers the lower case 30. Electronic components such as the relay 40, the fuse 60, and the bus bar 10 are attached to the lower case 30, and the upper case 20 covers some of these electronic components.

For convenience of description, the upper case 20 side will be referred to as the upper side, and the lower case 30 side will be referred to as the lower side.

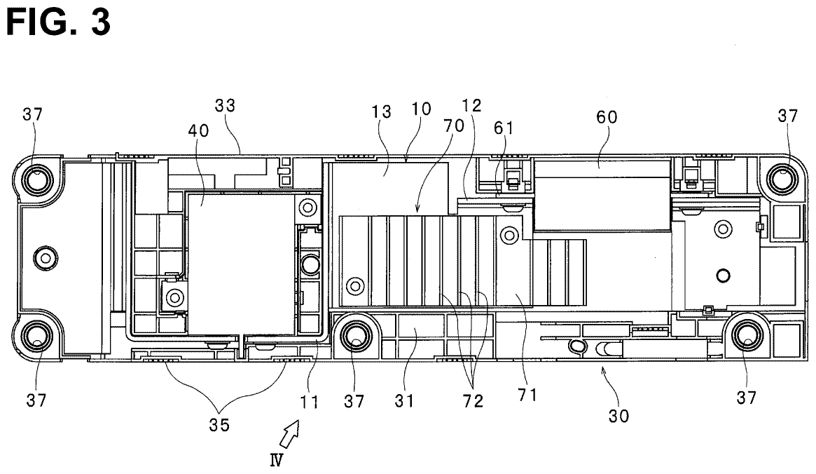

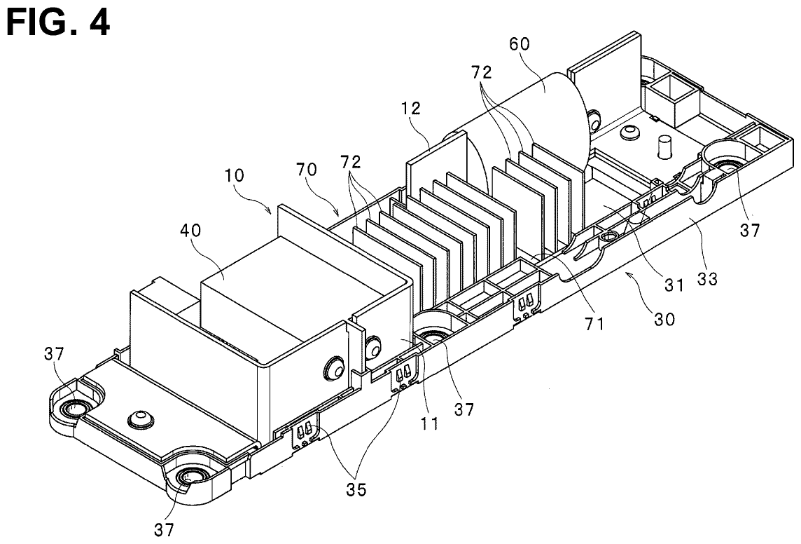

FIG. 3 is a plan view showing the electrical junction box 100 according to the first embodiment with the upper case 20 removed, and FIG. 4 is a view taken along an arrow IV in FIG. 3.

The lower case 30 is shaped as a flattened box that is open on the upper case 20 side. The lower case 30 has a substantially rectangular bottom wall 31 (fixing wall) whose outer side is in contact with and fixed to the target object, and also has side walls 33 that extend perpendicularly from the edge of the bottom wall 31 toward the upper case 20. As described above, the relay 40, the fuse 60, and the bus bar 10 are provided inside the lower case 30.

Among the side walls 33 of the lower case 30, the outer surfaces of the side walls 33 on the long sides of the bottom wall 31 include a plurality of engagement projections 35 that engage with later-described engagement portions 25 of the upper case 20. The engagement projections 35 are provided in pairs, each pair including two projections spaced apart from each other in the length direction of the side walls 33.

Furthermore, the bottom wall 31 is provided with fixing holes 37, which are formed at the four corners and in the vicinity of the side wall 33 on one long side and are used when attaching the lower case 30 (housing 50) to the target object.

As shown in FIGS. 3 and 4, in the lower case 30, the relay 40 and the fuse 60 are spaced apart from each other in the length direction of the lower case 30. Specifically, the relay 40 is arranged on one end side of the lower case 30, and the fuse 60 is arranged on the other end side of the lower case 30. The fuse 60 is provided in the vicinity of one side wall 33 on one side in the width direction of the lower case 30. Also, the relay 40 is provided with connection terminals on the side corresponding to the other side wall 33 on the other side in the width direction (see FIG. 4).

The bus bar 10 is provided between the relay 40 and the fuse 60. The bus bar 10 is substantially plate-shaped, is constituted by a conductive metal plate made of copper or the like, and is arranged opposing the inner surface of the bottom wall 31. The bus bar 10 includes a flattened portion 13 opposing the bottom wall 31, one end portion 11 (connection portion) screwed to one connection terminal of the relay 40, and another end portion 12 (connection portion) screwed to a connection terminal 61 of the fuse 60. Hereinafter, the one end portion 11 and the other end portion 12 will also be referred to as the two end portions 11 and 12.

Specifically, the bus bar 10 includes the other end portion 12 that is rectangular plate-shaped and connected perpendicularly to the edge of the flattened portion 13 in the vicinity of the fuse 60, and the one end portion 11 that is rectangular plate-shaped and connected perpendicularly to the edge of the flattened portion 13 in the vicinity of the relay 40. The one end portion 11 extends in the width direction of the bottom wall 31, and then the end portion on the side corresponding to the side wall 33 on the other side is bent along the side wall 33 on the other side and connected to one connection terminal of the relay 40.

The one end portion 11 and the other end portion 12 are provided with fixing through holes for screw fastening. For example, the other end portion 12 and the one end portion 11 are provided with elliptical fixing through holes (not shown), thus allowing for design errors and tolerances.

The bus bar 10 is provided such that one main surface of the flattened portion 13 opposes the bottom wall 31. The heat dissipation member 70 that dissipates heat generated by the bus bar 10 when energized is screwed to the flattened portion 13 of the bus bar 10. The heat dissipation member 70 extends over the majority of the flattened portion 13, including the vicinity of the one end portion 11 and the vicinity of the other end portion 12.

The heat dissipation member 70 has a comb-like shape in a vertical cross section taken in the length direction of the lower case 30, and includes a base plate 71 and a plurality of heat dissipation fins 72 (heat dissipation plates).

The base plate 71 is made of a material that has good thermal conductivity, such as aluminum, and is substantially rectangular. One main surface (first main surface) of the base plate 71 is in contact with the other main surface of the flattened portion 13 of the bus bar 10. The heat dissipation fins 72 are provided on the other main surface (second main surface) of the base plate 71.

The heat dissipation fins 72 are rectangular plate-shaped and are made of the same material as the base plate 71. For example, the heat dissipation fins 72 and the base plate 71 are integrally formed as a single piece. The heat dissipation fins 72 are provided standing approximately perpendicularly from the base plate 71. The heat dissipation fins 72 are arranged side by side at predetermined intervals in the lengthwise direction of the bottom wall 31.

The upper case 20 is shaped as a box that is open on the side facing the lower case 30. The upper case 20 is slightly smaller than the lower case 30 in terms of both the dimension in the length direction and the dimension in the width direction perpendicular to the length direction.

The upper case 20 has a ceiling wall 21 opposing the bottom wall 31 of the lower case 30, and side walls 22 that are provided around the edge of the ceiling wall 21 and extend toward the lower case 30 (see FIG. 1).

Furthermore, a plurality of through holes 23 (first through holes) are formed in the ceiling wall 21 of the upper case 20. More specifically, a plurality of through holes 23 are formed in the majority of the ceiling wall 21, including the vicinity of the bus bar 10. The through holes 23 extend along the ceiling wall 21.

Among the through holes 23, the through holes 23 located in the vicinity of the bus bar 10 in particular are formed at positions that correspond to the gaps between adjacent heat dissipation fins 72, with respect to the direction in which the ceiling wall 21 opposes the bottom wall 31 of the lower case 30 (hereinafter simply referred to as the opposing direction) (see FIG. 2). In other words, the area directly below each through hole 23 corresponds to the area between a pair of adjacent heat dissipation fins 72. Each through hole 23 has a substantially rectangular shape extending along the heat dissipation fins 72. In particular, the through holes 23 provided in the vicinity of the bus bar 10 extend along the gaps between adjacent heat dissipation fins 72.

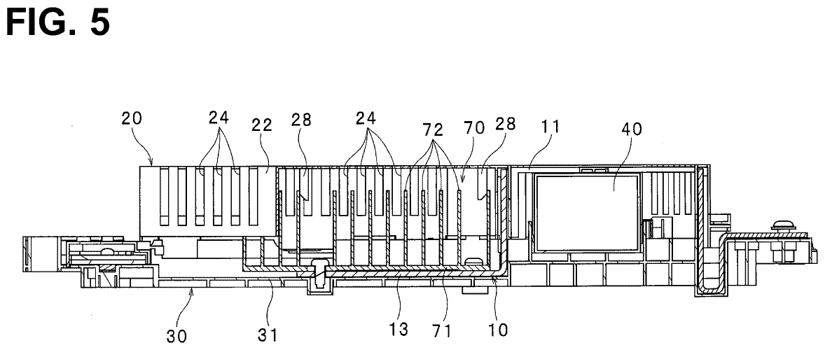

FIG. 5 is a cross-sectional view taken along a line V-V in FIG. 2.

Furthermore, positioning portions 28 protrude from the inner surface of the ceiling wall 21 and determine the position of the heat dissipation member 70 (heat dissipation fins 72) during assembly. The positioning portions 28 are provided in the vicinity of the heat dissipation fins 72 at the two ends in the arrangement direction in which the heat dissipation fins 72 are arranged side by side. More specifically, with respect to the opposing direction, one positioning portion 28 is provided at a position corresponding to the gap between the heat dissipation fin 72 at one end and the heat dissipation fin 72 adjacent thereto, and the other positioning portion 28 is provided at a position corresponding to the gap between the heat dissipation fin 72 at the other end and the heat dissipation fin 72 adjacent thereto. The positioning portions 28 have a rectangular shape in vertical cross section and determine the position of the heat dissipation member 70 by the leading end portions abutting against the inner surfaces of the heat dissipation fins 72 at the two ends.

In the upper case 20, a plurality of side-wall through holes 24 (second through holes) are formed in the two side walls 22 opposing each other in the width direction of the ceiling wall 21, and extend to the edge portions of the ceiling wall 21. Specifically, a plurality of side-wall through holes 24 are formed in one side wall 22 that faces the fuse 60 and the other side wall 22 that faces the connection terminals of the relay 40. The side-wall through holes 24 are particularly concentrated in the vicinity of the bus bar 10, that is, in the vicinity of the through holes 23. The side-wall through holes 24 are formed at regular intervals in the length direction of the upper case 20.

The side-wall through holes 24 of the one side wall 22 and the side-wall through holes 24 of the other side wall 22 are formed at positions aligned with each other in the width direction of the ceiling wall 21 (i.e., the opposing direction in which the one side wall 22 and the other side wall 22 oppose each other). Also, the side-wall through holes 24 of the one side wall 22 and the side-wall through holes 24 of the other side wall 22 are formed at positions corresponding to gaps between adjacent heat dissipation fins 72 in the width direction of the ceiling wall 21 (see FIGS. 2 and 5).

Therefore, the heat dissipation fins 72 are not positioned between the side-wall through holes 24 of the one side wall 22 and the side-wall through holes 24 of the other side wall 22, which correspond to each other in the width direction of the ceiling wall 21, but rather the gaps between adjacent heat dissipation fins 72 are formed between corresponding side-wall through holes 24.

The side-wall through holes 24 of the one side wall 22 and the side-wall through holes 24 of the other side wall 22 have a substantially rectangular shape extending along the opposing direction. In particular, the side-wall through holes 24 provided in the vicinity of the bus bar 10 extend along the gaps between adjacent heat dissipation fins 72.

Each of the through holes 23 and each of the side-wall through holes 24 of the upper case 20 has a width of, for example, several mm, which is small enough to prevent the insertion of the fingertips of a person handling the case.

A plurality of engagement portions 25 for engaging with the engagement projections 35 of the lower case 30 are provided at locations on the lower end portions of the side walls 22. Each of the engagement portions 25 is U-shaped, with two end portions on the open side that are fixed to the side wall 22, and a curved portion that protrudes downward from the side wall 22. When assembling the upper case 20 and the lower case 30, the engagement projections 35 of the lower case 30 pass between the edges of the side walls 22 and the curved portions of the engagement portions 25 on the inward side of the engagement portions 25, and thus the engagement projections 35 engage with the engagement portions 25 (see FIG. 1).

In the electrical junction box 100, a current in the range of 300 A to 1000 A is used. When a current flows, heat is generated by the relay 40 and the fuse 60, and the heat from the relay 40 and the fuse 60 is immediately transferred to the bus bar 10 that is in direct contact with them. The heat generated by the relay 40 and the fuse 60 may adversely affect the electronic components around the relay 40, the fuse 60, and the bus bar 10, and therefore need to be cooled quickly. However, the extent of heat dissipation due to the dissipation of heat from the relay 40 and the fuse 60 themselves cannot be expected to be large, and heat dissipation via the bus bar 10 connected to the relay 40 and the fuse 60 is more efficient.

To address this, in the electrical junction box 100 of the present embodiment, the bus bar 10 is provided with the heat dissipation member 70. During energization, heat transferred from the relay 40 and the fuse 60 to the bus bar 10 and heat generated in the bus bar 10 is quickly transferred to the base plate 71 of the heat dissipation member 70, which is in direct contact with the bus bar 10, and is dissipated into the air via the heat dissipation fins 72. Therefore, the heat generated by the relay 40 and the fuse 60 can be efficiently dissipated via the bus bar 10, and the heat generated in the bus bar 10 can also be properly dissipated, thus making it possible to prevent the problems described above.

Furthermore, a large current (e.g., 1000 A) cannot be used for a long period of time due to safety concerns and the problem of a large amount of heat being generated in the bus bar 10, and therefore is used intermittently for short periods of time. In this way, when a large current is used, the time for which the large current flows is short, and therefore rather than heat being generated throughout the entire bus bar 10, heat generation is concentrated at the portions connected to the relay 40 and the fuse 60, that is, at the two end portions 11 and 12 of the bus bar 10.

To address this, in the electrical junction box 100 of the present embodiment, portions of the heat dissipation member 70 (heat dissipation fins 72) are disposed in the vicinity of the one end portion 11 and the other end portion 12 of the bus bar 10. Therefore, as described above, even when a large current flows and heat generation is concentrated at the two end portions 11 and 12 of the bus bar 10, heat from the bus bar 10, the relay 40, and the fuse 60 can be effectively dissipated.

In the electrical junction box 100 of the present embodiment, the through holes 23 and the side-wall through holes 24 are formed in the upper case 20 in the vicinity of the bus bar 10 as described above. Therefore, air can easily flow into the bus bar 10 and the heat dissipation member 70 from the outside, thereby improving the air-cooling effect.

Furthermore, in the electrical junction box 100 of the present embodiment, as described above, the through holes 23 of the upper case 20 are formed at positions corresponding to the gaps between adjacent heat dissipation fins 72, in the opposing direction in which the ceiling wall 21 and the bottom wall 31 oppose each other. Also, the side-wall through holes 24 of the upper case 20 are formed at positions corresponding to the gaps between adjacent heat dissipation fins 72, with respect to the width direction of the ceiling wall 21. Therefore, outside air flows in between the adjacent heat dissipation fins 72, and inside air flows out from between the adjacent heat dissipation fins 72 quickly without remaining inside.

As described above, the side-wall through holes 24 of the one side wall 22 and the side-wall through holes 24 of the other side wall 22 are formed at positions aligned with each other in the width direction of the ceiling wall 21, and the gaps between adjacent heat dissipation fins 72 are formed between the side-wall through holes 24 of the one side wall 22 and the side-wall through holes 24 of the other side wall 22.

Therefore, for example, air flowing in through the side-wall through holes 24 of the one side wall 22 (the side-wall through holes 24 of the other side wall 22) passes between adjacent heat dissipation fins 72 and quickly flows out through the side-wall through holes 24 of the other side wall 22 (the side-wall through holes 24 of the one side wall 22). At this time, convection air containing heat from the heat dissipation fins 72 also flows out from the housing 50, thus further improving the effect of cooling the relay 40, the fuse 60, and the bus bar 10.

As described above, the through holes 23 provided in the vicinity of the bus bar 10 are formed at positions corresponding to the gaps between adjacent heat dissipation fins 72, in the opposing direction in which the ceiling wall 21 opposes the bottom wall 31 of the lower case 30. Therefore, when convection air containing heat from the heat dissipation fins 72 rises between adjacent heat dissipation fins 72, the air quickly flows to the outside of the housing 50 through the through holes 23 directly above. Therefore, the effect of cooling the relay 40, the fuse 60, and the bus bar 10 can be further improved.

### Second Embodiment

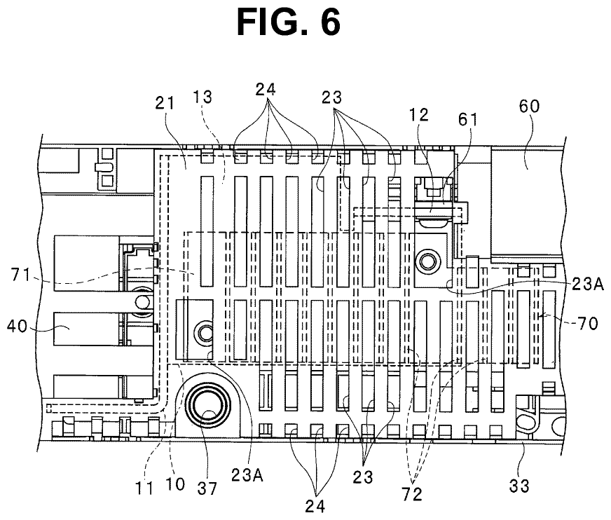

FIG. 6 is a partial plan view of an electrical junction box 100 according to a second embodiment. For convenience, FIG. 6 shows an enlarged view of the vicinity of the bus bar 10, and the positions of the bus bar 10 and heat dissipation member 70 are indicated by dashed lines.

Similarly to the first embodiment, in the electrical junction box 100 of the second embodiment, a plurality of through holes 23 (first through holes) are formed in the ceiling wall 21 of the upper case 20 in the vicinity of the bus bar 10, and a plurality of side-wall through holes 24 (second through holes) are formed in the side walls 22 in the vicinity of the bus bar 10.

Similarly to the first embodiment, the through holes 23 provided in the vicinity of the bus bar 10 are formed at positions corresponding to gaps between adjacent heat dissipation fins 72, in the opposing direction in which the ceiling wall 21 and the bottom wall 31 oppose each other. In other words, the area directly below each through hole 23 corresponds to the area between a pair of adjacent heat dissipation fins 72. Each through hole 23 has a substantially rectangular shape extending along the heat dissipation fins 72.

In the electrical junction box 100 of the second embodiment, among the through holes 23, through holes 23A formed in the vicinity of the one end portion 11 and the other end portion 12 of the bus bar 10 are larger than the other through holes 23. For example, the through holes 23A are larger than the other through holes 23 in terms of the dimension in the arrangement direction in which the through holes 23 are arranged side by side.

Aspects of the side-wall through holes 24 are similar to the first embodiment, and a detailed description thereof will be omitted.

As described above, in the electrical junction box 100 of the second embodiment, among the through holes 23, the through holes 23A formed in the vicinity of the one end portion 11 and the other end portion 12 of the bus bar 10 are larger than the other through holes 23. Therefore, the amount of air flowing in through the through holes 23A is relatively larger, thereby making it possible to more intensively cool the one end portion 11 and the other end portion 12, and making it possible to accommodate the case where heat generation is concentrated at the two end portions 11 and 12 of the bus bar 10 when a large current flows.

Portions similar to those in the first embodiment are given the same reference numerals, and detailed description thereof will be omitted.

### Third Embodiment

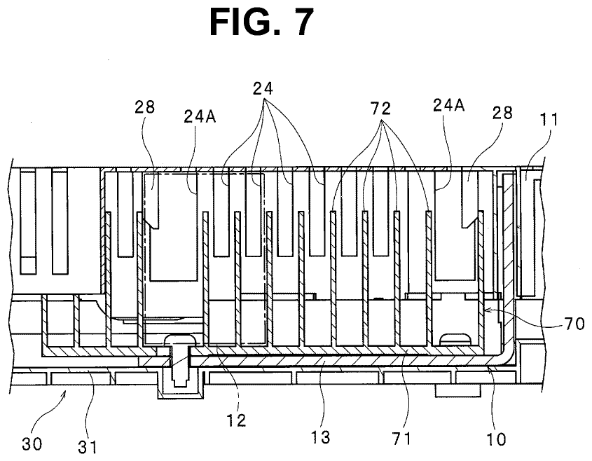

FIG. 7 is a partial vertical cross-sectional view of an electrical junction box 100 according to a third embodiment. For convenience, FIG. 7 shows an enlarged view of the vicinity of the heat dissipation member 70, and the position of the other end portion 12 is indicated by dashed-dotted lines.

Similarly to the first embodiment, in the electrical junction box 100 of the third embodiment, a plurality of through holes 23 (first through holes) are formed in the ceiling wall 21 of the upper case 20 in the vicinity of the bus bar 10, and a plurality of side-wall through holes 24 (second through holes) are formed in the side walls 22 in the vicinity of the bus bar 10.

Similarly to the first embodiment, in the upper case 20, a plurality of side-wall through holes 24 (second through holes) are formed in the one side wall 22 and the other side wall 22, which oppose each other in the width direction of the ceiling wall 21. The side-wall through holes 24 are particularly concentrated in the vicinity of the bus bar 10, that is, in the vicinity of the through holes 23.

The side-wall through holes 24 of the one side wall 22 and the side-wall through holes 24 of the other side wall 22 are formed at positions aligned with each other in the width direction of the ceiling wall 21, and the side-wall through holes 24 of the one side wall 22 and the side-wall through holes 24 of the other side wall 22 are formed at positions corresponding to gaps between adjacent heat dissipation fins 72 in the width direction of the ceiling wall 21 (see FIGS. 2 and 7). The side-wall through holes 24 extend along the gaps between adjacent heat dissipation fins 72, and have a substantially rectangular shape.

In the electrical junction box 100 of the third embodiment, as shown in FIG. 7, among the side-wall through holes 24, side-wall through holes 24A formed in the vicinity of the one end portion 11 and the other end portion 12 of the bus bar 10 are larger than the other side-wall through holes 24. Although only the other side wall 22 is shown in FIG. 7, the side-wall through holes 24 in the one side wall 22 and the side-wall through holes 24 in the other side wall 22 both include side-wall through holes 24A that are larger than the other side-wall through holes 24, in the vicinity of the two end portions 11 and 12.

For example, the side-wall through holes 24A are larger than the other side-wall through holes 24 in terms of the dimension in the arrangement direction in which the side-wall through holes 24 are arranged side by side, or the ratio of the side-wall through hole to the gap between the pair of adjacent heat dissipation fins 72 is larger than the other side-wall through holes 24.

Aspects of the through holes 23 are similar to the first embodiment, and a detailed description thereof will be omitted.

As described above, in the electrical junction box 100 of the third embodiment, among the side-wall through holes 24, the side-wall through holes 24A formed in the vicinity of the one end portion 11 and the other end portion 12 of the bus bar 10 are larger than the other side-wall through holes 24. Therefore, the amount of air flowing in through the side-wall through holes 24A is relatively larger, thereby making it possible to more intensively cool the one end portion 11 and the other end portion 12, and making it possible to accommodate the case where a large current flows and heat generation is concentrated at the two end portions 11 and 12 of the bus bar 10.

Portions similar to those in the first embodiment are given the same reference numerals, and detailed description thereof will be omitted.

### Fourth Embodiment

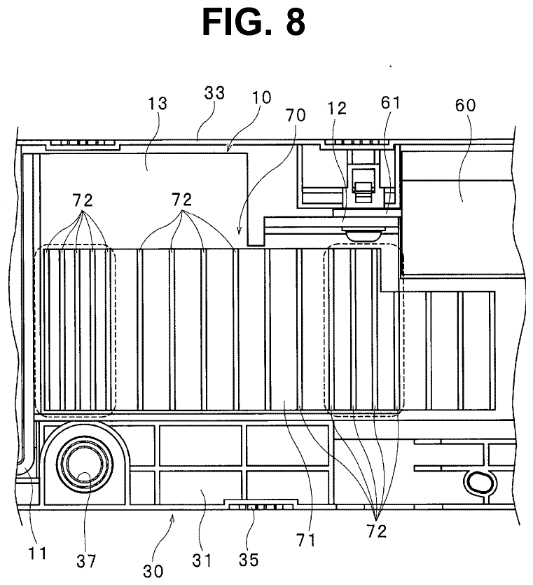

FIG. 8 is a plan view of an electrical junction box 100 of a fourth embodiment with the upper case 20 removed. For convenience, FIG. 8 shows an enlarged view of the vicinity of the heat dissipation member 70.

Similarly to the first embodiment, the electrical junction box 100 of the fourth embodiment includes the bus bar 10, the flattened portion 13 of the bus bar 10 is arranged opposing the bottom wall 31, and the heat dissipation member 70 is attached to the flattened portion 13 to dissipate heat generated by the bus bar 10 during energization. The heat dissipation member 70 has a comb-like shape in a vertical cross section extending in the length direction of the lower case 30, and includes a base plate 71 and a plurality of heat dissipation fins 72 (heat dissipation plates).

The base plate 71 is made of a material that has good thermal conductivity, such as aluminum, and has a rectangular shape. One main surface of the base plate 71 is in contact with the other main surface of the flattened portion 13 of the bus bar 10, and a plurality of heat dissipation fins 72 are provided on the other main surface.

The heat dissipation fins 72 are rectangular plate-shaped and are made of the same material as the base plate 71. For example, the heat dissipation fins 72 and the base plate 71 are integrally formed as a single piece. The heat dissipation fins 72 are provided standing approximately perpendicularly from the base plate 71. The heat dissipation fins 72 are arranged side by side in the lengthwise direction of the base plate 71.

In the electrical junction box 100 of the fourth embodiment, the number of heat dissipation fins 72 is greater in the vicinity of the one end portion 11 and the other end portion 12 of the bus bar 10 (see the regions indicated with dashed lines in FIG. 8) than in other regions. In other words, the heat dissipation fins 72 are arranged in a concentrated manner in the vicinity of the one end portion 11 and the other end portion 12 of the bus bar 10.

In this way, in the electrical junction box 100 of the fourth embodiment, a larger number of heat dissipation fins 72 are arranged in the vicinity of the one end portion 11 and the other end portion 12 of the bus bar 10 than in other regions, and as the number of heat dissipation fins 72 increases, the amount of surface area available for heat dissipation increases, thereby improving the heat dissipation performance in the vicinity of the two end portions 11 and 12. Therefore, it is possible to more intensively cool the one end portion 11 and the other end portion 12, and it is possible to accommodate the case where heat generation is concentrated at the two end portions 11 and 12 of the bus bar 10 when a large current flows.

Portions similar to those in the first embodiment are given the same reference numerals, and detailed description thereof will be omitted.

The technical features (constituent elements) described in the first to fourth embodiments can be combined with each other, and by combining them, new technical features can be formed.

The embodiments disclosed herein should be considered in all respects as illustrative and not restrictive. The scope of the present invention is defined by the claims, not by the above meaning, and is intended to include all modifications within the meaning and scope equivalent to the claims.

The matter described in the respective embodiments can be combined with each other. Furthermore, the independent and dependent claims set forth in the claims can be combined with each other in any and all combinations, regardless of the form of reference. Furthermore, the claims are in a format in which a claim references two or more other claims (multiple dependent claim format), but are not limited to this format. It is also possible to use a format for describing multiple dependent claims (multi-multi claims) that cite at least one multiple dependent claim.

### List of Reference Numerals

10 Bus bar
11 One end
12 Other end
13 Flattened portion
20 Upper case
21 Ceiling wall
22 Side wall
23 Through hole
24, 24A Side-wall through hole
25 Engagement portion
28 Positioning portion
30 Lower case
31 Bottom wall
33 Side wall
35 Engagement projection
37 Fixing hole
40 Relay
50 Housing
60 Fuse
61 Connection terminal
70 Heat dissipation member
71 Base plate
72 Heat dissipation fin
100 Electrical junction box
200 Battery pack

1. An electrical junction box comprising:
a housing in which an electronic component is provided, the housing having a fixing wall configured to be fixed to a target object;
a plate-shaped bus bar arranged opposing the fixing wall and connected to the electronic component; and
a plurality of heat dissipation plates provided standing in a direction intersecting the bus bar, and configured to dissipate heat from the bus bar,
wherein a pair of side walls extending toward the fixing wall are provided in the housing at respective opposing edges of an opposing wall that opposes the fixing wall,
a second through hole is formed in each of the side walls,
the heat dissipation plates extend in an opposing direction in which the pair of side walls oppose each other, and
the second through hole of one of the side walls and the second through hole of another one of the side walls are formed at positions corresponding to a gap between an adjacent pair of the heat dissipation plates, so as to oppose each other in the opposing direction.

2. The electrical junction box according to claim 1, further comprising:
a base plate having a first main surface in contact with a main surface of the bus bar,
wherein the plurality of heat dissipation plates are provided on a second main surface of the base plate.

3. The electrical junction box according to claim 2,
wherein a first through hole is formed in the opposing wall, and
the first through hole is formed at a position that, with respect to an opposing direction in which the fixing wall and the opposing wall oppose each other, corresponds to a gap between an adjacent pair of the heat dissipation plates.

4. The electrical junction box according to claim 3,
wherein the first through hole extends along the heat dissipation plates.

5. (canceled)

6. The electrical junction box according to claim 1,
wherein the second through holes extend along the plurality of heat dissipation plates.

7. The electrical junction box according to claim 2,
wherein the base plate and the plurality of heat dissipation plates are integrally formed as a single piece, and
the opposing wall is provided with a positioning portion configured to position the plurality of heat dissipation plates.

8. The electrical junction box according to claim 1,
wherein the plurality of heat dissipation plates are provided in a vicinity of a connection portion between the bus bar and the electronic component.

9. The electrical junction box according to claim 8,
wherein a larger number of the heat dissipation plates are provided in a vicinity of the connection portion than in another region.

10. The electrical junction box according to claim 3,
wherein a plurality of the first through holes are provided, and
among the plurality of first through holes, a first through hole formed in a vicinity of a connection portion between the bus bar and the electronic component is larger than the other first through holes.

11. The electrical junction box according to claim 1,
wherein a plurality of the second through holes are provided, and
among the plurality of second through holes, a second through hole formed in a vicinity of a connection portion between the bus bar and the electronic component is larger than the other second through holes.
